(19) United States
(12) Patent Application Publication
(10) Pub. No.: US 2005/0027921 A1
(43) Pub. Date: Feb. 3, 2005

(54) Information processing apparatus capable of prefetching instructions

(76) Inventors: Teppei Hirotsu, Hitachi (JP); Kotaro Shimamura, Hitachinaka (JP); Noboru Sugihara, Kokubunji (JP); Yasuhiro Nakatsuka, Tokai (JP); Teruaki Sakata, Hitachi (JP)

Correspondence Address: MCDERMOTT, WILL & EMERY, 600 13th Street, N.W., Washington, DC, 20005-3096, US

(21) Appl. No.: 10/842,638

(22) Filed: May 11, 2004

(30) Foreign Application Priority Data
May 12, 2003 (JP) 2003-133355

(51) Int. Cl. G11C 5/00

(52) U.S. Cl. 711/1

(57) ABSTRACT

A prefetch address calculation unit detects a branch instruction and a data access instruction to be reliably executed from a series of instruction included in an entry that is stored in a buffer at 1 cycle and outputs a prefetch request of its target address to a control unit. Then, decoding types of the series of instruction that is included in the entry, and setting it at an instruction type flag, the prefetch address calculation unit masks the output of the instruction type flag that has been executed by using an address signal of the instruction that is being executing presently and outputs a location of the instruction for issuing a prefetch request. By a signal from a control unit, the prefetch address calculation unit clears an instruction type flag corresponding to the instruction that issued the prefetch request.

### BACKGROUND OF THE INVENTION

The present invention relates to a prefetching technology of a branch instruction and a data access instruction in an information processing apparatus that is provided with a CPU, a memory, and a prefetching buffer.

On one hand, an operating frequency of a CPU has been improved dramatically in rate years, and on the other hand, improvement of an operating frequency of a memory is slower as compared to that of the operating frequency of the CPU so as to respond to high-capacity. Thus, the operating frequencies of the CPU and the memory are deviated from each other, so that a problem such that the performance of the entire system is not improved becomes significant.

In order to solve this problem, the improvement of the performance has been generally performed by storing instructions necessary for a prefetching buffer capable of reading the data at high speed or a cache in advance and reading the instructions from these, delay of reading a memory is concealed.

When a program executed has a branch instruction, it is necessary to predict an instruction specified by a branch target address in an appropriate manner and perform prefetching the instruction in the prefetching buffer or the like.

As this prediction method, it is considered that, on the basis of a branch history table, the branch target address is predicted and the predicted instruction specified by the branch target address has been read from the memory to the prefetching buffer in advance. However, this involves a problem such that, when the processing is branched in actual by the branch instruction, if the above-described prediction is performed upon executing the instruction, the prefetching of a series of instruction after branching is not in time.

Therefore, as disclosed in JP-A-6-274341, a method is considered, whereby a possibility of branch is predicted upon prefetching of the instruction and a later series of instruction is prefetched.

### SUMMARY OF THE INVENTION

The technology disclosed in JP-A-6-274341 still has a problem such that a performance of the system is not improved with respect to a program only prefetching the branch target address of the branch instruction and having many data accesses.

A processor of a fixed length instruction that is common in later years, in order to treat the data with a bit width more than the length instruction, adds a program counter value in the processor and a constant (an immediate value) embedded in an instruction code upon execution, and waits for a PC-relative data access instruction with this addition value as an address of an address target.

However, differently from the branch instruction, in the case of the data access instruction, after the data access occurs in accordance with this instruction, consequently, the previous series of instruction are executed.

According to a conventional art, such processing is not considered and the processing such as prefetching of the PC-relative data access instruction is not performed. Therefore, it is very difficult for the program having many data accesses to improve the performance thereof.

An object of the present invention is to provide a high-performance information processing technology for effectively prefetching the data even in a program having many data accesses without depending on the kinds of the programs.

In order to attain the above-described object, the present invention provides an information processing apparatus having a CPU, a memory, and a prefetching buffer mounted therein, which has a prefetch address calculation unit for outputting target addresses of a branch instruction and data access instruction before these instructions, reads the instruction or the data of the target address to be outputted from the prefetch address calculation unit in advance, and stores it in the prefetching buffer.

Specifically, the present invention provides An information processing apparatus comprising: a CPU; a memory; and a prefetch buffer for storing a series of instruction made of the predetermined number of instructions and data before the above-described CPU executes the instruction or the data in the above-described series of instruction; wherein the above-described information processing apparatus further includes prefetch address calculating means for selecting a prescribed branch instruction or data access instruction that is included in the above-described series of instruction at a point of time when the above-described series of instruction is stored in the above-described prefetch buffer and calculating a target address of the above-described selected instruction; and prefetch buffer storing means for determining whether or not the above-described series of instruction including the instruction or the data of the above-described target address that is calculated by the above-described prefetch address calculating means is stored in the above-described prefetch buffer, and if it is not stored therein, reading the above-described series of instruction from the above-described memory and storing it in the above-described prefetch buffer.

Other objects, features and advantages of the invention will become apparent from the following description of the embodiments of the invention taken in conjunction with the accompanying drawings.

### BRIEF DESCRIPTION OF THE DRAWINGS

FIG. 1 is an overall view of an information processing apparatus according to the present embodiment;

FIG. 2 is a view for explaining an example of a program to be executed by a CPU according to the present embodiment;

FIG. 3 is a view for explaining an example of the operation of the CPU according to the present embodiment;

FIG. 4 is a view for explaining an example of the operation of a memory according to the present embodiment;

FIG. 5 is a view for explaining arrangement of an instruction and the data when storing the program shown in FIG. 2 in the memory;

FIG. 6 is a detailed view of a tag and a prefetching buffer according to the present embodiment;

FIG. 7 is a detailed view of a read data selector according to the present embodiment;

FIG. 8 is a detailed view of a prefetch address calculation unit according to the present embodiment;

FIG. 9 is a detailed view of a target instruction selector according to the present embodiment;

FIG. 10 is a detailed view of an address calculation unit according to the present embodiment;

FIG. 11 is a timing chart showing the operation of the information processing apparatus according to the present embodiment; and

FIG. 12 is a timing chart showing the operation of a conventional information processing apparatus.

### DETAILED DESCRIPTION OF THE EMBODIMENTS

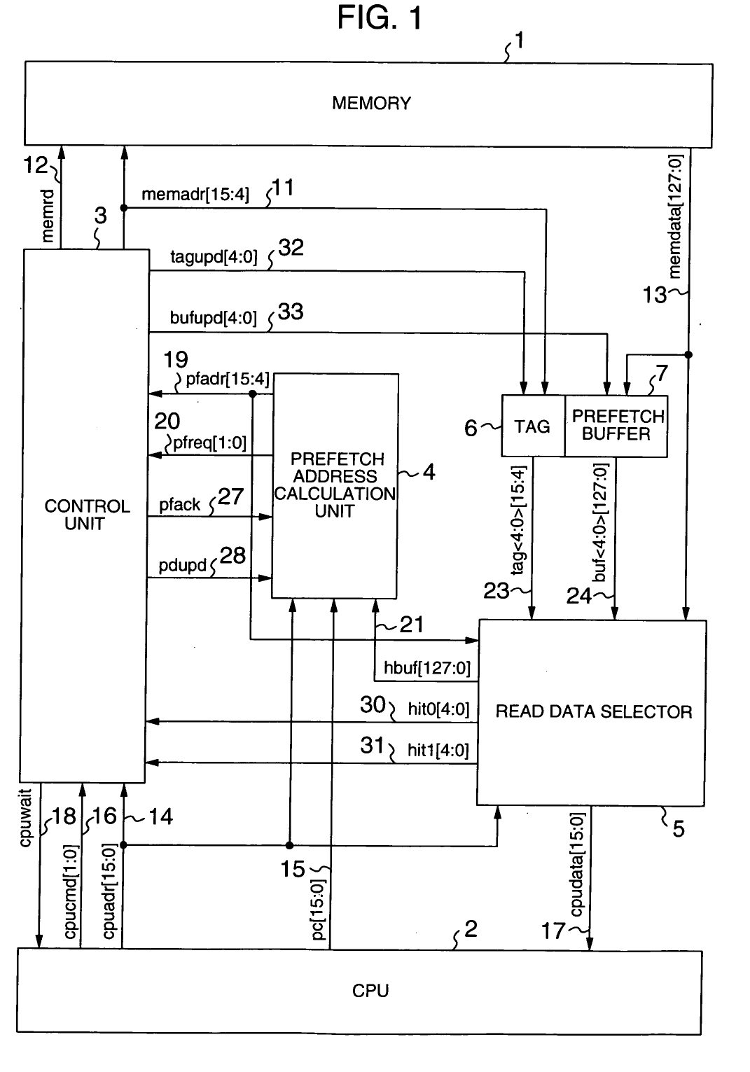

FIG. 1 is an overall view of an information processing apparatus according to the present embodiment.

The present information processing apparatus is composed of a memory (1), a CPU (2), a prefetch address calculation unit (4), a prefetch buffer (7), a tag (6), a read data selector (5), and a control unit (3).

The memory (1) may store a program. In the memory (1), a signal line 11 receives a memory address signal memadr [15:4], a signal line 12 receives a memory read signal memrd, and a signal line 13 outputs a memory read data signal memdata [127:0].

In this case, a notation of a memadr [15:0] collectively describes signals of 16 bits made of memadr [15], memadr [14], . . . , memadr [0] for convenience of notation. In the present specification, same applies to the other signals.

In the meantime, according to the present embodiment, it is assumed that an access latency of the memory is defined as 2 bits and a reading width is defined as 128 bits.

The CPU (2) may read a necessary instruction code from the memory (1) or the like and may execute the program. The CPU (2) is provided with an arithmetic logic unit including an ALU (an arithmetic logic unit) for performing a numerical calculation and a logical calculation that are necessary for the data stored in the memory or the like, a program counter, an accumulator, a general-purpose register or the like; and an operation control unit for generating an operation control signal of the foregoing arithmetic logic unit by decoding the inputted instructions (they are not illustrated).

The CPU (2) may output a CPU address signal cpuadr [15:0] indicating an instruction code as an access target of the CPU (2) and an address of the data with a signal line 14; and may output a CPU instruction signal cpucmd [1:0] indication the access kinds of the CPU with a signal line 16. The kinds of the access indicated by the CPU instruction signal will be described later.

The CPU (2) may further output a program counter signal pc [15:0] indicating an address of the instruction which has being executed presently by the CPU (2) for calculation of the prefetch address calculation unit (4) with a signal line 15. The prefetch address calculation unit (4) may acquire an address of a branch target by using the pc [15:0] and the immediate value within the instruction code.

In the CPU (2), the instruction in the address indicated by the cpuadr [15:0] or the CPU read data signal cpudata [15:0] as the read value of the data are further inputted from the read data selector (5) with a signal line 17.

In the CPU (2), the instruction in the address indicated by the cpuadr [15:0] or the CPU read data signal cpudata [15:0] as the read value of the data are further inputted from the read data selector (5) with a signal line 17.

In the meantime, according to the present embodiment, it is assumed that the instruction of the CPU (2), the data width, and an address space are defined as 16 bits, respectively.

When the series of instruction composed of a prescribed number of instructions or data is stored in the prefetch buffer (7), the prefetch address calculation unit (4) may detect the branch instruction and the data access from instruction from among the stored series of instruction before the instructions are executed; may calculate a target address to be accesses next in accordance wit these instructions; and may generate a request to read the instruction raw including this target address from the memory (1) to the prefetch buffer (7).

In this case, hereinafter, in the present specification, the branch instruction and the data access instruction are referred to as a prefetching request instruction. In addition, calculating the target address to be accessed next in accordance with the prefetching request instruction, the request to read the series of instruction including this target address from the memory (1) to the prefetch buffer (7) is referred to as a prefetch request.

The prefetch address calculation unit (4) may output a prefetch address signal pfadr [15:0] indicating the target address of the prefetching request instruction with a signal line 19 and may output a prefetch address signal pfreq [15:0] indicating that the prefetching request occurs with a signal line 20 to the control unit (3), respectively.

The prefetch address calculation unit (4) may further accept the cpuadr [15:0] and a pc [15:0] from the CPU (2); may accept a hit buffer output signal hbuf [127:0] from the read data selector (5) with a signal line 21; may accept a signal pfack from the control unit (3) with a signal line 27; and may accept a prefetching update signal pdupd indicating an input timing of a hbuf [127:0] with a signal line 28 to use these signals for calculating the pfaudr [15:0] and the pfreq [1:0]. The pfack is a signal to be outputted in the case that, after processing the prefetching request in accordance with the prefetching request instruction that is abstracted from among a prescribed series of instruction, the prefetching request instruction should be further abstracted from among the same series of instruction to carry on the prefetching request. The detail description of these pfack and hbuf will be described later.

Before the CPU (2) executes the prefetching request instruction, the prefetch buffer (7) may read the target address instruction or the data of this prefetching request instruction from the memory (1) and store it in preparation for the access to the target address of this prefetching request instruction.

The prefetch buffer (7) may receive the input of a buffer update signal bufupd [4:0] indicating an update timing of a value that is held by the prefetch buffer with a signal line 33 and may take into a signal of a memdata [127:0].

In addition, the prefetch buffer (7) may output a prefetch buffer signal buf <4.0>[127:0] indicating a hit buffer with a signal line 24. In this case, a notation of the buf <4.0>[127:0] collectively describes five signals of a buf 4 [127:0], a buf 3 [127:0], . . . , buf 0 [127:0] for convenience of notation.

A tag (6) may hold an address of the instruction and the data that are held by the prefetch buffer (7).

The tag (6) may receive an input of a tag update signal, a tagupd [4:0] indicating a timing updating a value that is held by a signal line 32, and may receive a memadr [15:4].

In addition, the tag (6) may output an output signal <4:0>[15:4] indicating an address of the instruction and the data. In this case, a notation of the tag <4:0>[15:4] collectively describes five signals of a tag 4 [15:4], a tag 3 [15:4], . . . , tag 0 [15:4] for convenience of notation.

The read data selector (5) may detect whether or not the instruction or the data that is provided with the prefetch request by the prefetch address calculation unit (4) is held in the prefetch buffer (7). In this case, when the prefetch request is given by the prefetch address calculation unit (4), the control unit (3) may determine whether or not the prefetching should be carried out in accordance with the detection of this read data selector (5).

In addition, the read data selector (5) determines whether or not the instruction or the data provided with the access request from the CPU (2) is held in the prefetch buffer (7), and if it is held in the prefetch buffer (7), the read data selector (5) may output it from the prefetch buffer (7) to the CPU.

The read data selector (5) may output a comparison result of a tag <4:0>[127] and a pfadr [15:4] as a high order 15-4 bit of the pfadr [15:0] as a comparison signal, a hit0 [4:0], with a signal line 30 and it may output a comparison result of a tag <4:0>[127] and a cpuadr [15:4] as a high order 15-4 bit of the cpuadr [15:0] as a comparison signal, a hit1 [4:0], with a signal line 31. That is because 15-4 bit designates an unit upon reading the instruction and the data of entry as described later.

The read data selector (5) may further output a hit buffer signal hbuf [127:0] to be used for calculation of the prefetch address calculation unit (4) from among a buf <4:0>[127:0] and a memdata [127:0] to the prefetch address calculation unit (4) with the signal line 21.

The read data selector (5) may further select the instruction and the data of which accesses are requested at the cpuadr [15:0] from among the buf <4:0>[127:0] and memdata [127:0] and may output them to the cpudata [15:0].

The control unit (3) may control transfer of the instruction and the data between the CPU (2) and the memory (1) by inputting and outputting a control signal in and from the CPU (2), the memory (1), the prefetch address calculation unit (4), the prefetch buffer (7), the tag (6), and the read data selector (5).

Specifically, as described later, by receiving the input of various control signals and asserting a necessary control signal at a prescribed timing, the processing of each part is controlled.

In the next place, the detail of each structure will be described. Prior to the detailed description, an example of the program to be executed by the CPU (7) that is assumed according to the present embodiment; the arrangement when this program is stored in a memory according to the present embodiment; and the operation of the CPU (7) will be described.

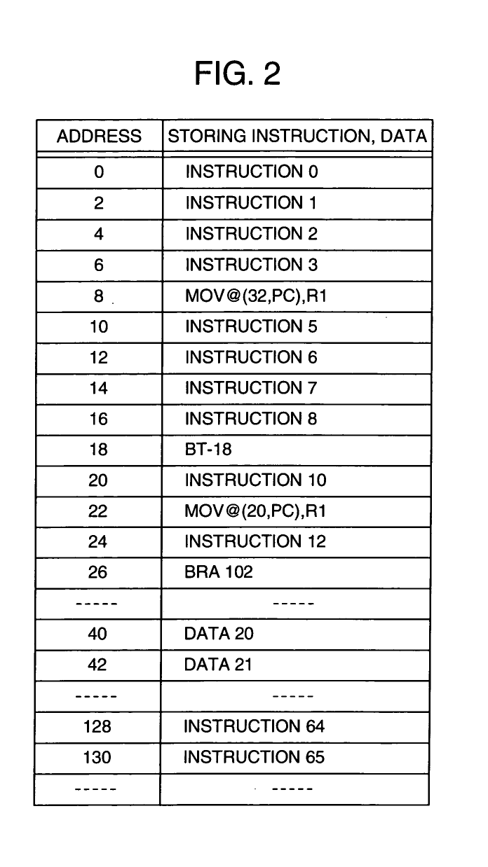

FIG. 2 shows an example of the program to be executed by the CPU (1).

The present program has a general instruction for processing sequentially from an address 0 in turn; the data access instruction for designating to access the prescribed data; a conditional branch instruction for shifting the process to a prescribed address when the condition permits; and a non-conditional branch instruction for shifting the process to a prescribed address unconditionally.

In the present drawing, a general instruction is represented by “instruction”, a data access instruction is represented by “MOV . . . ”, a conditional branch instruction is represented by “BT . . . ”, and a non-conditional branch instruction is represented by “BRA . . . ”.

In the present drawing, “MOV @ (32, PC), R1” of an address 8 represents the data access instruction for executing the process of “transfer the data of the address that 32 is added to the address of this instruction to R1”, and if this instruction is executed, the access to the data 20 located in an address 40 may occur. In the same way, if “MOV @ (20, PC), R1” of an address 22 is executed, the access to the data 21 located in an address 42 may occur. “BT-18” of an address 18 represents the conditional branch instruction for executing the process of “when a register T of the CPU=1, the data branches to an address that (−18) is added to the address of this instruction”. When this instruction is executed and the condition of the register T of the CPU=1 is met, the flow of the program may shift to the instruction of the address 0.

“BAR 102” of an address 26 may represent a non-conditional branch instruction for executing the process of “the data branches to an address that 102 is added to the address of this instruction”. When this instruction is executed, the flow of the program may shift to the instruction of an address 128 unconditionally.

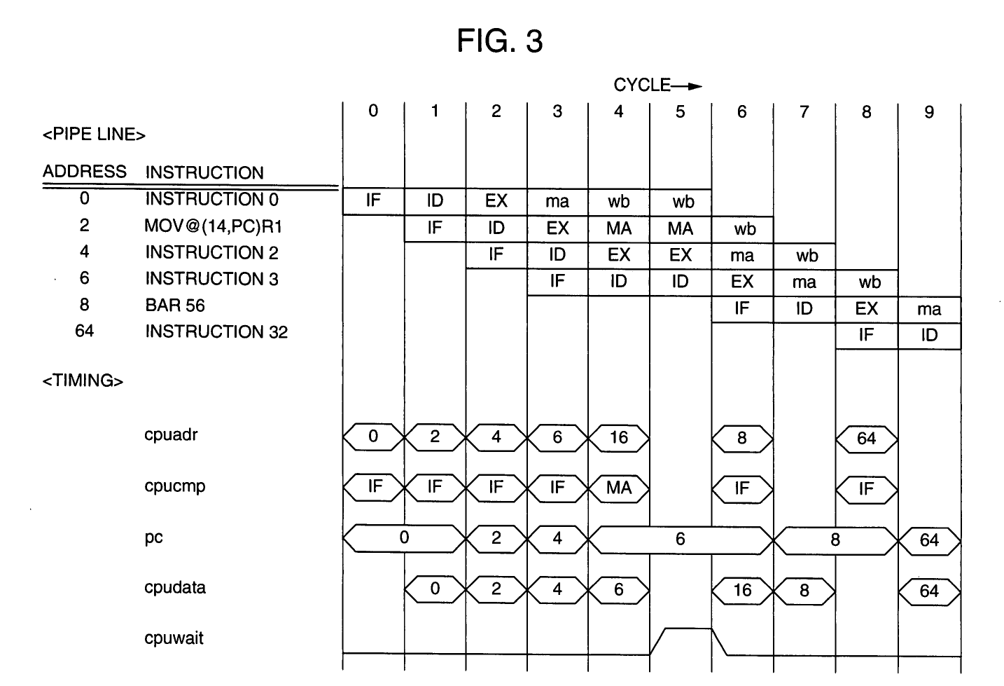

FIG. 3 is a timing chart showing the operation of the CPU (2).

An upper part of FIG. 3 shows an example of a series of instruction to be executed by the CPU (2), and shows the CPU (2)'s pipe line operation upon processing this series of instruction.

The CPU (2) may process one instruction by a 5-stage pipeline, namely, an instruction fetch (IF) stage reading the instruction from the memory (1); an instruction decode (ID) stage for decoding the instruction; an execution (EX) stage for executing the instruction; a memory access (MA) stage for reading the data from the memory (1); and a write back (WB) stage for writing the data in the memory (1).

In the meantime, the access to the memory (1) may occur at the IF stage, the MAX stage, and the WB stage of respective instruction. In addition, the IF stage, the ID stage, and the EX stage are always executed, however, the MAX stage and the WB stage are not executed according to circumstances. In the present drawing, the instruction stage that is not executed is represented by a small letter.

A lower part of FIG. 3 shows waveforms of respective input and output signals of the CPU (2), which occur in accordance with the pipeline operation shown by the upper part of FIG. 3.

In the present drawing, a cycle 0 is an IF stage of the instruction 0 of the address 0. At the cycle 0, 0 is outputted from the CPU (2) to a cpuadr and a signal (IF) showing instruction fetch to a cpucmd, so that an access to the instruction at the address 0 may occur.

In the meantime, according to the present embodiment, correspondence of an output value of a CPU command signal cpucmd [1:0] indicating the access kind of the CPU (2) and the access kind is defined as 2′b00: no operation (NOP), 2’b01: instruction fetch (IF), and 2’b10: memory access (MA).

In the follow-on cycle 1, the instruction of the address 0 to the access of the cycle 0 is inputted from the cpudata into the CPU (2).

In this case, a cycle 4 is a MA stage of the data access instruction “MOV @ (14, PC), R1” of an address 2. This instruction intends to transfer the data that is stored in an address 16 (=14+2) to a R1, so that 16 is outputted from the CPU (2) to the cpuadr, MA is outputted to the cpucmd, and the access to the data located in the address 16 may occur.

A cycle 5 indicates a condition such that the data to the access of the cycle 4 is not detected because of the output delay or the like of the memory. In this time, the control unit (3) asserts a cpuwait and instructs interruption of the instruction processing.

The data is detected in the follow-on cycle 6, and receiving negating of the cpuwait, the CPU (2) may restart the processing.

A cycle 8 is an EX stage of the branch instruction “BRA 56” of an address 8 and also is an IF stage of an instruction 32 located in an address 64 of a branch target. In the present cycle, 64 is outputted from the CPU (2) to the cpuadr and the IF is outputted to the cpucmd, so that the access to the instruction located in the address 64 may occur.

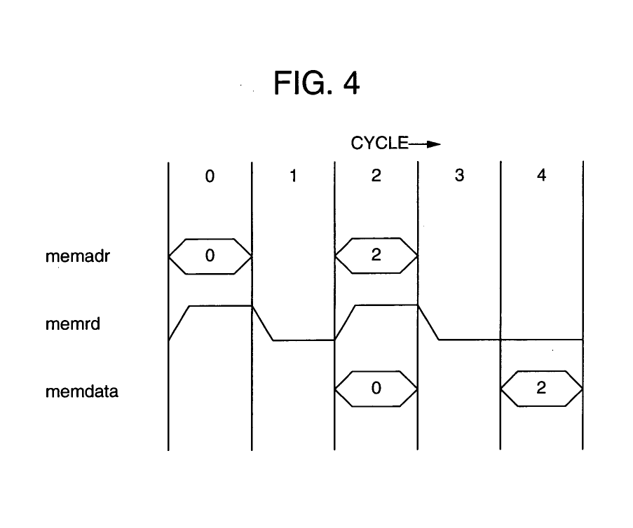

In the next place, the operation of the memory (1) upon executing the program shown in FIG. 3 will be described. FIG. 4 is a timing chart showing the operation of the memory (1) upon executing the program shown in FIG. 3.

In the cycle 0, the control unit (3) may give read request to the address 0 to the memory (1) by outputting 0 to the memadr and asserting a memrd. According to the present embodiment, since access latency of the memory is set at 2 cycle, the data to this access is detected at the cycle 2 and here, the memory (1) may output the instruction or the data to a memdata.

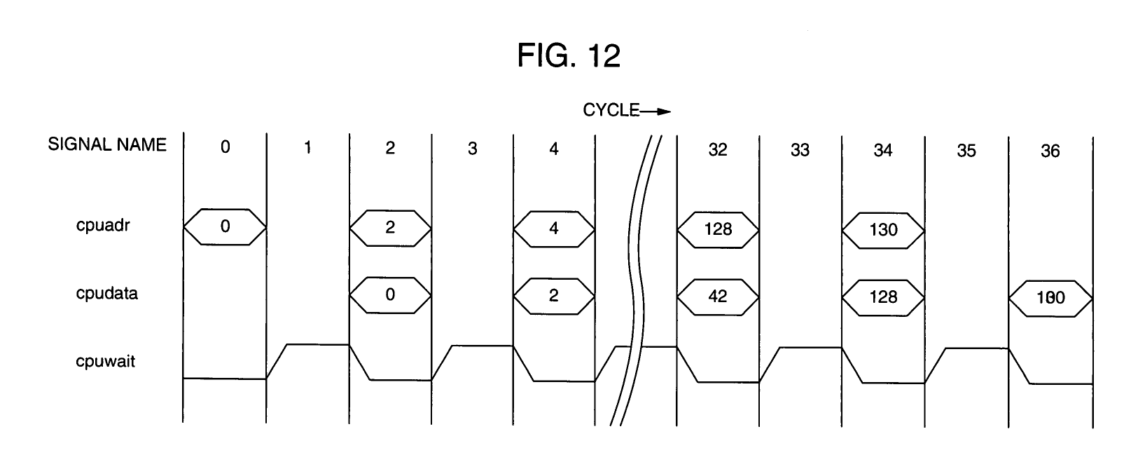

If storing the program shown in FIG. 2 in the memory (1) waiting for such access latency 2 and executing it without a structure to prefetch the prefetching request instruction, as shown in FIG. 12, the cpuwait is asserted by 1 cycle to the CPU for each memory access and this results in deterioration of a performance.

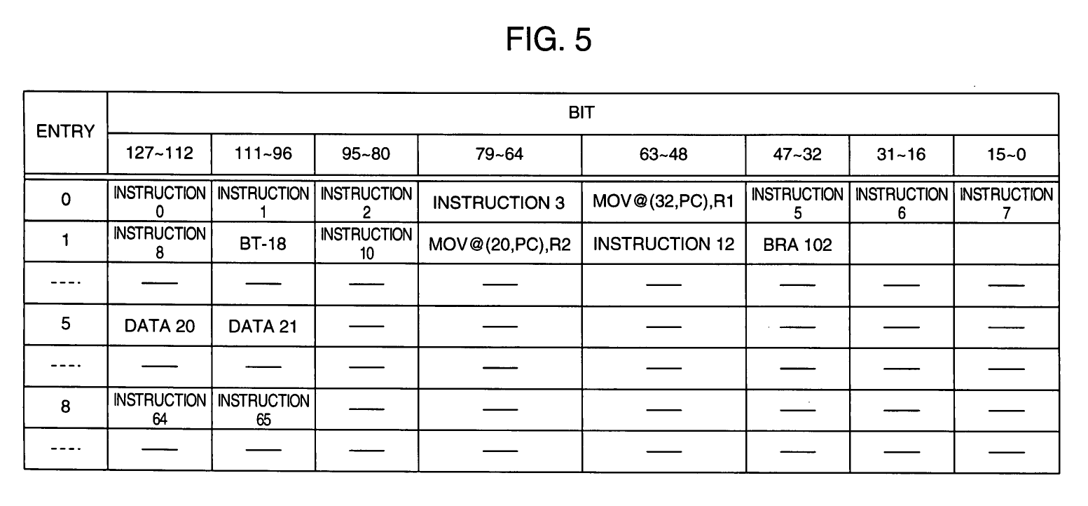

FIG. 5 schematically illustrates the arrangement of the instruction and the data when storing the program shown in FIG. 2 in the memory (1) according to the present embodiment.

As shown in the present drawing, the instruction and the data structuring the program are arranged from the side of a larger bit in the order of the small address in turn to make 1 entry in units of the instruction (or the data) of 8. Hereinafter, a series of the instruction or the data to make 1 entry is referred to as a series of instruction.

In the meantime, according to the present embodiment, the access to the memory (1) is carried out in units of entry. For example, the access to the addresses 0, 2, 4, 5, 8, 10, 12, and 14 are carried out simultaneously as the access to entry 0.

When storing the instruction or the data with a 16 bit width in the memory (1), each bit of the address has a roll for distinguishing the followings. Bit 15-4: entry, Bit 3-1: location of the instruction or the data in the same entry, Bit 0: upper 8-bit and lower 9-bit of the instruction or the data Next, based on the premise of the storage condition or the like of such a program, the operation of the CPU, and the instruction and the data of the memory, the details of the tag (6), the prefetch buffer (7), the read data selector (5), and the prefetch address calculation unit (4) are described below, which are briefly described with reference to FIG. 1.

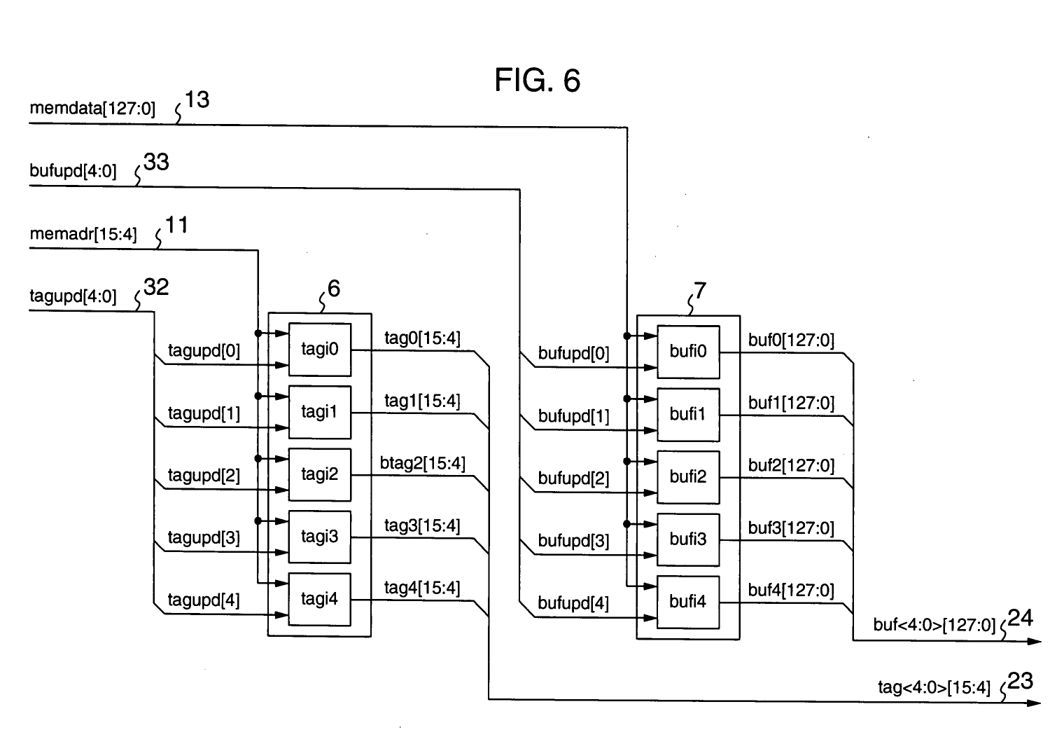

FIG. 6 is a detailed view of the tag (6) and the prefetching buffer (7). According to the present embodiment, a structure of providing five buffers as the prefetching buffer (7) is taken as an example to be described. It is a matter of course that the number of the buffers is not limited to this.

The tag (6) is made of storage elements with a 12 bit width, namely, a tagi0, a tagi1, . . . , a tagi4.

The tagi0, the tagi1, . . . , the tagi4 may take in the output of a memadr [15:4] at an assert timing of a tagupd [0], a tagupd [1], . . . , a tagupd [4], and they may output the taken values to a tag0 [15:4], a tag1 [15:4], . . . , a tag4 [15:4].

The prefetch buffer (7) is structured by storage elements with a 128 bit width, namely, a bufi0, a bufi1, . . . , a bufi4.

The bufi0, the bufi1, . . . , the bufi4 may take in the output of a memdata [127:0] at an assert timing of a bufupd [0], a bufupd [1], . . . , a bufupd [4], and they may output the taken values to a buf0 [127:0], a buf1 [127:0], . . . , a buf4 [127:4].

The tagi0, the tagi1, . . . , the tagi4 may store the entry of the series of instruction that is stored in the bufi0, the bufi1, . . . , the bufi4, respectively.

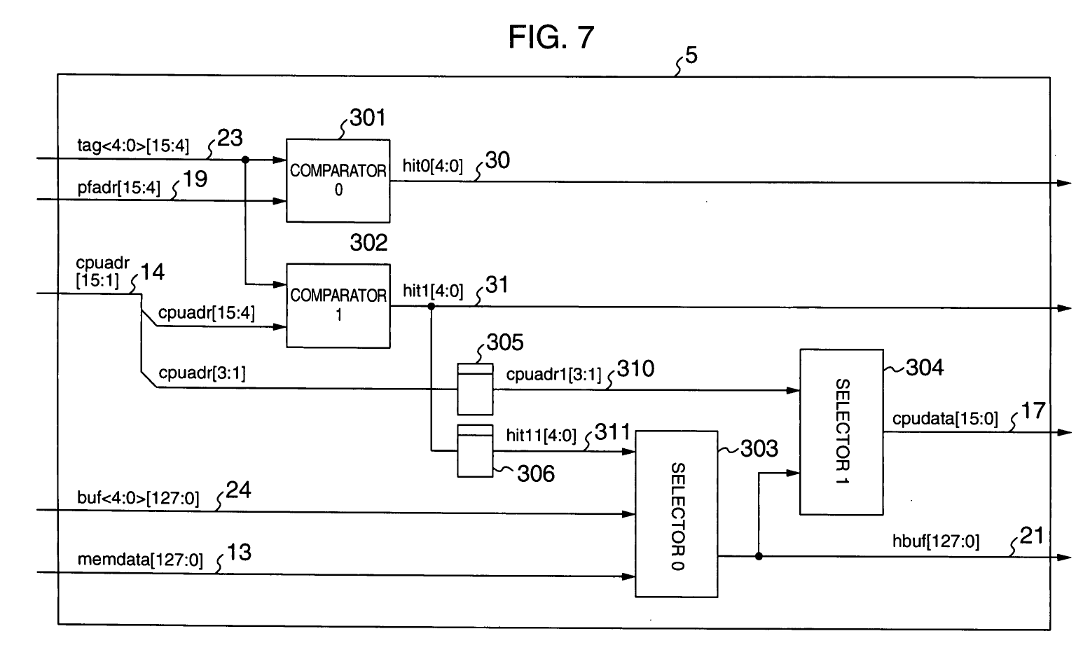

FIG. 7 is a detailed view of the read data selector (5).

The read data selector (5) is structured by a comparator 0 (301), a comparator 1 (302), a 3-bit storage element (305), a 5-bit storage element (306), a selector 0 (303), and a selector 1 (304).

The comparator 0 (301) may compare the tag <4:0>[15:4] with the pfadr [15:4] and may output its result to the hit0 [4:0].

Each bit of the hit0 [4:0] is calculated by the following logic equation.
A hit0[$i]=(tag$I[15:4]==pfadr[15:4])$i=0, 1, 2, 3, 4

The hit0 [4:0] is a signal indicating a result of detecting whether or not the entry provided with the prefetching request from the prefetch address calculation unit (4) is held by the prefetch buffer (7) (detection at prefetch buffer hit) in the read data selector (5). Hereinafter, the case that this entry is held therein is referred to as a buffer hit, and the case that it is not held therein is referred to as a buffer-miss hit. In addition, when it is held in a buffer n (n=0, 1, 2, 3, 4), this is referred to as a prefetch buffer n hit.

In this case, the control unit (3) may determine whether or not the prefetching should be carried out in accordance with the detection of the inputted hit0 [4:0]. In other words, the control unit (3) may control so as not to carry out prefetching on buffer hit and may control to carry out prefetching on buffer-miss hit.

For example, in the case of hit0 [0]=1, the entry provided with prefetching request means that the entry has been already held in the bufi0 (prefetch buffer 0 hit) and in this case, there is no need to prefetch again.

According to the present embodiment, thus, the prefetch buffer hit of the target address that is provided with the prefetching request is detected. In other words, it is detected whether or not the entry including the instruction of this address has been already stored in the prefetch buffer (7) before executing the prefetching in practice. By such prefetching control, it is possible to prohibit the wasteful prefetching.

The comparator 1 (302) may compare the tag <4:0>[15:4] with the cpuadr [15:4] and may output its result to the hit1 [4:0].

Each bit of the hit1 [4:0] is calculated by the following logic equation.
The hit 1[$i]=(tag$I[15:4]==cpuadr[15:4])$i=0, 1, 2, 3, 4

The hit1 [4:0] is a signal indicating a result of detecting whether or not the entry including the instruction or the data having the access request from the CPU (2) is held by the prefetch buffer (7) (detection at prefetch buffer hit) in the read data selector (5). The definitions of the buffer hit, the buffer-miss hit, and the prefetch buffer n hit are the same as the case of the hit0 [4:0].

The control unit (3) may determine whether or not the instruction or the data having the access request from the CPU (2) should be read from the prefetch buffer (7) or from the memory (1) in accordance with the detection of the inputted hit1 [4:0]. In other words, the control unit (3) may control so as to read it from the prefetch buffer (7) on the buffer hit and may control to read it from the memory (1) on the buffer-miss hit.

For example, the hit1 [0]=1 (the prefetch buffer 0 hit) means that the entry including the instruction or the data having the access request is held in the bufi0. In this case, the control unit (3) may select the instruction or the data as the access target from the output buf0 [127:0] of the bufi0 and may output it to the CPU (2).

Thus, according to the present embodiment, if the access target is held in the prefetch buffer (7), by outputting the instruction or the data from there to the CPU (2), the high-speed access can be realized.

The above-described processing for selecting the instruction or the data from the prefetch buffer output of buf <4:0>[127:0] on the buffer hit may be carried out by the 3-bit storage element (305), the 5-bit storage element (306), the selector 0 (303), and the selector 1 (304).

The 3-bit storage element (305) is a flip-flop operating in synchronization with a clock of the CPU (2), and receiving the input of a cpuadr [3:1], the 3-bit storage element (305) may output a cpuadr1 [3:1] with a signal line 310.

The 5-bit storage element (306) is a flip-flop operating in synchronization with a clock of the CPU (2), and receiving the input of the hit1 [4:0], the 5-bit storage element (306) may output a hit11 [4:0] with a signal line 311.

The read data selector (5) may synchronize the outputs of the cpuadr1 [3:1] and the hit11 [4:0] with the read data output timing that is after the CPU access by one cycle by receiving the cpuadr [3:1] and the hit1 [4:0] as described above at the flip-flop once by means of the 3-bit storage element (305) and the 5-bit storage element (306), and outputting the same value after one cycle to the cpuadr1 [3:1] and the hit11 [4:0].

The selector 0 (303) has the hit11 [4:0] as a select signal and may output the signals selected from the buf0 [127:0], a buf2 [127:0], . . . , a buf3 [127:0] and the memdata [127:0] to the hbuf [127:0].

In this case, a relation between the value of the hit11 [4:0] and the selected signal is defined as follows:
5′b00001: buf0 [127:0]
5′b00010: buf1 [127:0]
5′b00100: buf2 [127:0]
5′b01000: buf3 [127:0]
5′b10000: buf4 [127:0]

Except for the above, it is defined as the memdata [127:0].

Hereby, in the selector 0 (303), on the buffer hit, the output of the hit buffer is selected; and on the buffer-miss hit, the memdata [127:0] is selected.

The selector 1 (304) may select one of the instruction or the data designated by the cpuadr1 [3:1] from among the series of instruction included in the entry that is outputted by the hbuf [127:0] and may output it to the cpudata [15:0].

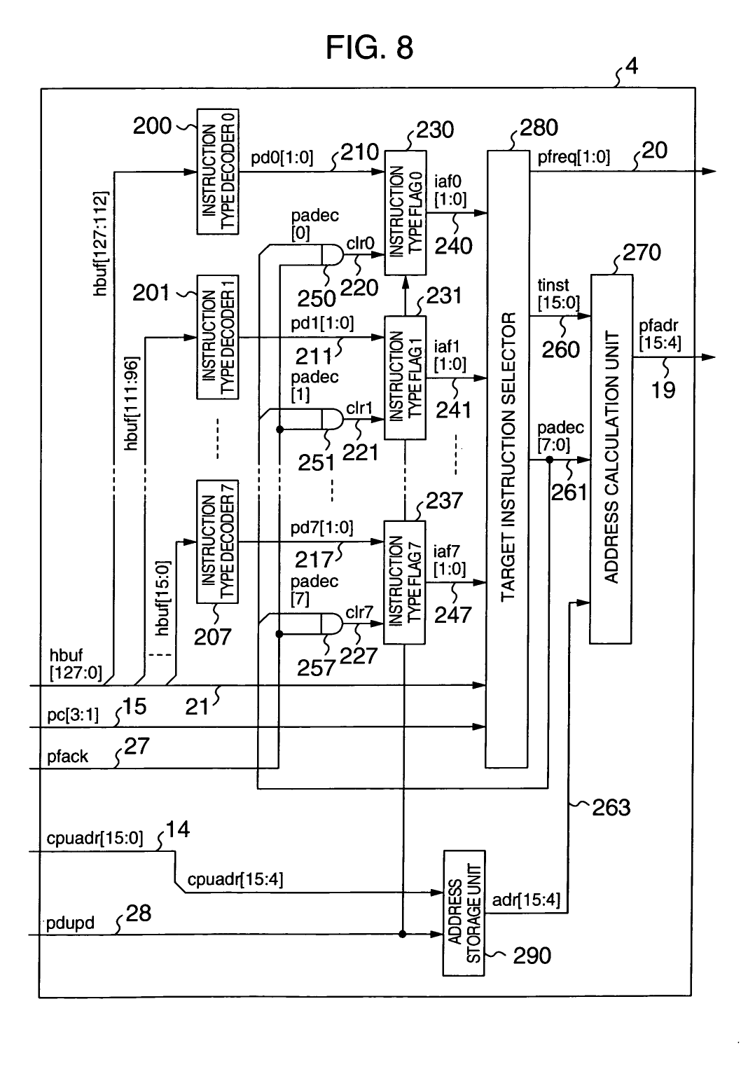

Next, the detail of the prefetch address calculation unit (4) will be described. FIG. 8 is a detailed view of the prefetch address calculation unit (8).

The prefetch address calculation unit (4) is provided with eight instruction type decoder for decoding the inputted instruction kinds, namely, an instruction type decoder 0 (200), an instruction type decoder 1 (201), . . . , an instruction type decoder 7 (207); eight AND gates, namely, an AND gate 0 (250), an AND gate 1 (251), . . . , an AND gate 7 (257); eight instruction type flags, namely, an instruction type flag 0 (230), an instruction type flag 1 (231), . . . , an instruction type flag 7 (237); a target instruction selector (280); an address calculation unit (270); and an address storage unit (290).

The hbuf [127:0] is partitioned for each 16 bits and each segment is inputted in the instruction type decoder 0 (200), the instruction type decoder 1 (201), . . . , the instruction type decoder 7 (207).

For example, in the instruction type decoder 0 (200), the instruction or the data of a head address in the series of instruction of the entry that is outputted by the hbuf [127:0] is inputted. The instruction type decoder 0 (200) may decode the type of the inputted instruction or the inputted data and may output its result to a signal pd0 [1:0] with the signal line (210).

In the meantime, the meaning of the output signal pd0 [1:0] is defined as 2′b01: the data access instruction capable of calculating the target address at the address calculation unit (270); 2′b10: the conditional branch instruction capable of calculating the target address at the address calculation unit (270); 2′b11: the non-conditional branch instruction capable of calculating the target address at the address calculation unit (270); and 2′b00: the instruction or the data other than the above.

In the same way, the instruction type decoder 1 (201) may decode the types of the second instruction or data in the series of instruction of the entry to be outputted by the hbuf [127:0] and may output its result as a signal pd1 [1:0] with a signal line (211).

Further, the types of the third, fourth, sixth instruction or data are also decoded in the same way. Then, the instruction type decoder 7 (207) may also decode the types of the eighth instruction or data in the series of instruction of the entry to be outputted by the hbuf [127:0] and may output its result as a signal line (217) with a pd 7 [1:0].

The pd0 [1:0], the p1 [1:0], . . . , the pd7 [1:0] are held in the instruction type frag 0 (230), the instruction type flag 1 (231), . . . , the instruction type flag 7 (237), respectively, at a timing that a pdupd (23) to be outputted by the control unit (3) is asserted.

The values that are held in the instruction type flag 0 (230), the instruction type flag 1 (231), . . . , the instruction type flag 7 (237) are outputted, respectively as a signal ifa0 [1:0] with a signal line 240; as a signal ifa1 [1:0] as a signal line 241; and as a signal ifa7 [1:0] with a signal line 242.

The target instruction selector (280) may select a prefetching request instruction to calculate the target address from among the instruction of the entry to be outputted by the hbuf [127:0] in accordance with the type of the instruction indicated by the inputted signal while accepting inputs of the ifa0 [1:0], the ifa1 [1:0], . . . , ifa7 [1:0], and the hbuf [127:0]; and may output it as a signal tinst [15:0] with a signal line 260.

For example, when the series of instruction of the entry 0 shown in FIG. 5 is inputted, the data access instruction of the instruction 4 is selected; and when the series of instruction of the entry 1 is inputted, the branch instruction of the instruction 9 is selected.

The target instruction selector (280) may further acquire the address of the instruction that is being executed presently by the CPU (2) by using the inputted pc [3:1] and may limit the instruction to be selected to the instruction of the address on and after the address of the instruction which is being executed presently.

The target instruction selector (280) may further output the type of the selected instruction as the pfreq [1:0]. In this case, the meaning of the output signal pfreq [1:0] is the same as the meanings of the pd0 [1:0], the pd1 [1:0], . . . , the pd7 [1:0] and indicates that the prefetching request is given from the prefetch address calculation unit (4) at a value other than 2′b00.

In this case, the control unit (3) may assert the pfack in accordance with the value of the pfreq that is inputted from the prefetch address calculation unit (4).

A relation between the value of the pfreq and with or without of the pfack assert is defined as follows:
Pfreq [1:0]=assert 2′b01:pfack
Pfreq [1:0]=not assert 2′b10.: pfack
Pfreq [1:0]=not assert 2′b11:pfack

In the case of prfreq [1:0]=2′b01, the instruction that is selected at that point is the data access instruction. Accordingly, the instruction on and after the data access instruction within the entry should be always executed. Therefore, with respect to the instruction on and after this data access instruction within the entry, with or without of the prefetching request instruction is detected; and if there is the prefetching request instruction, it is necessary to request prefetching.

In the case of pfreq [1:0]=2′b10, the instruction that is selected at that time is the conditional branch instruction. Accordingly, it cannot be determined whether or not the instruction on and after this conditional branch instruction within the entry is executed unless this conditional branch instruction is executed in the CPU (2). In other words, it is determined that this conditional branch instruction is not branched at the ID stage of the next instruction thereof. At that point of time, the value of the PC becomes an address of the next instruction of this conditional branch instruction, and as described later, in the target instruction selector (280), this conditional branch instruction is masked and with or without of the prefetching request instruction is detected with respect to the instruction on and after this conditional branch instruction within the entry.

In the case of pfreq [1:0]=2′b11, the instruction that is selected at that point of time is the non-conditional branch instruction. Accordingly, the instruction on and after this non-conditional branch instruction within the entry is not executed. Therefore, it is not necessary to detect the types of the instruction with respect to the later instruction and to examine the necessity of the prefetching.

The target instruction selector (280) may further output a signal padec [7:0] indicating a location of the instruction that is selected with a signal 261.

In this case, the meaning of the padec [7:0] is defined as 8′b00000001: select a top instruction, 8′b00000010: select a second instruction, . . . , 8′b10000000: select an eight instruction.

A logical multiplication between each bit of the padec [7:0] and pfack is generated by using the AND gate 0 (250), the AND gate 1 (251), . . . , the AND gate 7 (257); and a clear signal clr0 of the instruction type flag 0 is outputted with a signal line 220, a clear signal cdr1 of the instruction type flag 1 is outputted with a signal line 221, and a clear signal clr7 of the instruction type flag 7 is outputted with a signal line 227.

Thus, by using the asserted pfack and clearing the instruction type flag of the instruction that has been selected presently, the instruction can be prevented from being selected at a later timing. In other words, it is possible to select the later prefetching request instruction from the instruction on and after the instruction that has been selected presently within the same entry.

The address storage unit (290) holds an entry value including the series of instruction that is a target of calculation presently for the prefetch address calculation unit (4). Specifically, the address storage unit (290) holds an output value of the cpuadr [15:4] at an assert timing of pdupd and outputs the held value to an address signal adr [15:4] with a signal line (263).

The address calculation unit (270) may calculate the target address of the prefetching request instruction included in the series of instruction as a target of calculation presently for the prefetch address calculation unit (4). Specifically, the address calculation unit (270) may calculate the prefetching target address signal, pfadr [15:4] from the inputted padec [7:0], tinst [15:0], and adr [15:4] and may output it. The pfadr [15:4] may indicate the entry including the target address of the prefetching request instruction that is outputted as a tinst [15:0].

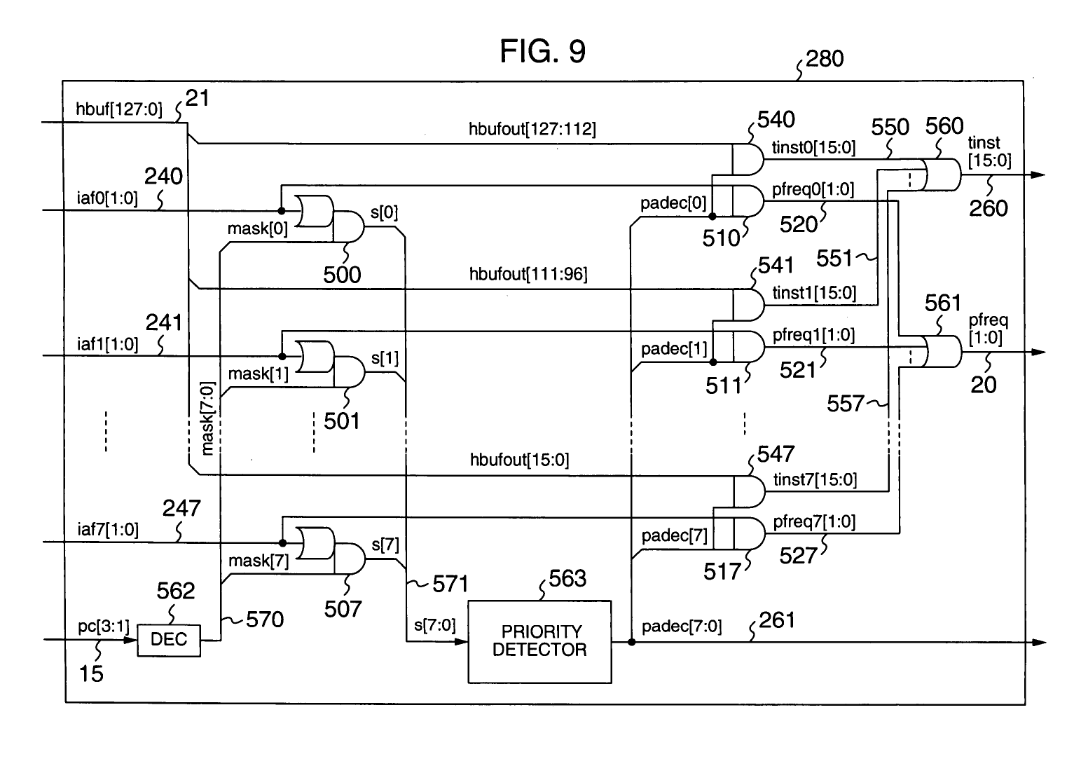

Next, the detail of the structure of the target instruction selector (280) will be described below, and a method for selecting the prefetching request instruction requiring prefetching is shown. FIG. 9 is a detailed view of the target instruction selector (280).

As shown in the present drawing, the pc [3:1] is decided into 8 bits by a decoder (562) as follows:
3′b000−>8′b11111111
3′b001−>8′b11111110
3′b010−>8′b11111100
3′b011−>8′b11111000
3′b100−>8′b11110000
3′b101−>8′b11100000
3′b110−>8′b11000000
3′b111−>8′b10000000
   Then, the decoded pc [3:1] is outputted as a selection mask signal mask [7:0] with a signal line 570.

Then, a result of masking the logical addition of each bit of the iaf0 [1:0] by a mask [0] is outputted as a signal s [0] through a combinational logic gate 0 (500). With respect to an iaf1 [1:0], . . . , an iaf7 [1:0], as same as the iaf0 [1:0], a result of masking the logical addition of each bit by a mask [1] . . . , mask [7], respectively, is outputted as a signal s[1], . . . , a signal s[7] through a combinational gate 1 (501), . . . , a combinational gate 7 (501).

The outputted signal s [7:0] is inputted in a priority detector (563) to be outputted as a padec [7:0] in accordance with a predetermined following correspondence.

In this case, a correspondence between input and output of the priority detector (563) is defined as follows:
8′b???????1−>8′b00000001
8′b??????10−>8′b00000010
8′b?????100−>8′b00000100
8′b????1000−>8′b00001000
8′b???10000−>8′b00010000
8′b??100000−>8′b00100000
8′b?1000000−>8′b01000000
8′b10000000−>8′b10000000
other than the above−>8′b0000000

In the meantime, “?” means “don't care”. In other words, it does not matter whether 1 or 0.

By this priority detector (563), the prefetching request instruction to be executed at first within the entry is outputted as a padec [0]. In addition, according to the present structure, the instruction and before the instruction that has been executed presently in the CPU (2) shown by the pc [3:1] is not selected in this priority detector 563 because the output of the signal s becomes 0 by the mask [0], . . . , the mask [7].

The padec [0] outputted from the priority detector 563 is used to mask a hbuf [127: 112] in an AND gate 00 (540), and its result is outputted to a tinst0 [15:0] with a signal line 550.

With respect to an hbuf [111:96], . . . , an hbuf [15:0], as same as a hbuf [127:112], the result of masking by the padec [1], . . . , the padec [7] is outputted to a tinst1 [15:0], . . . , a tinst7 [15:0], respectively, by an AND gate 01 (541), . . . , an AND gate 07 (547).

A result of masking an iaf0 [1:0] by the padec [0] is outputted to a pfreq0′ [1:0] by an AND gate 10 (510) with a signal line 520.

With respect to an iaf1 [1:0], . . . , an iaf7 [1:0], as same as the iaf1 [1:0], the result of masking by the padec [1], . . . , the padec [7] is outputted to a pfreq1 [1:0] . . . , a pfreq7 [1:0], respectively, by an AND gate 17 (512).

A logical addition of the tinst0 [15:0], . . . , the tinst7 [15:0] is calculated by an OR gate (560), and its result is outputted to the tinst [15:0]. Then, a logical addition of a pfreq0 [1:0], . . . , a pfreq7 [1:0] is calculated, and its result is outputted to the pfreq [1:0].

As described above, by the circuit described with reference to FIG. 9, the prefetching request instruction to be stored in the address on and after the instruction that has been executed presently by the CPU and be executed at first in the series of instruction in the entry to be outputted by the hbuf [127:0] is outputted to the tinst [15:0]. In addition, the type of the instruction outputted to the tinst [15:0] is outputted to the pfreq [1:0].

According to the above-described structure, the prefetch address calculation unit (4) can detect the branch instruction and the data access instruction to be reliably executed from the series of instruction included in the entry that is stored in the buffer in 1 cycle and can output the prefetching request of its target address to the control unit (3).

Specifically, the prefetch address calculation unit (4) decodes the types of the series of instruction included in the entry and sets them in the instruction type flag 0 (230), . . . , the instruction type flag 7 (237), respectively. Then, the prefetch address calculation unit (4) masks the output of the instruction type flag that has been executed by using the address signal of the instruction that is being executed presently. The priority detector (563) outputs the location of the instruction to issue the prefetching request of the target address from the output of the masked instruction type flag. Then, due to the pfack signal from the control unit (3), the priority detector (563) clears the instruction type flag corresponding to the instruction that issued the prefetching request to the target address.

In this case, the instruction to be selected in the target instruction selector (280) is the instruction on and after the address of the instruction that is being executed presently and the prefetching request instruction to be executed at first in the entry decoding the instruction types. Then, if the selected prefetching request instruction is the data access instruction, further, in the instruction on and after this instruction, with or without of the prefetching request instruction is detected. Then, if there is the prefetching request instruction, it is selected by the same procedure. When the selected prefetching request instruction is the conditional branch instruction, this selected instruction is executed and when it is decided that the branch is not carried out and the later instruction is executed, with or without of the prefetching request instruction is detected in the same way in the instruction on and after this selected instruction. Then, if there is the prefetching request instruction, it is selected. When the selected prefetching request instruction is the non-conditional branch instruction, nothing is executed for the instruction on and after this selected instruction.

In the meantime, according to the structure to only interpret the most prior branch instruction and only know the entry including its target address, even if the selected instruction is the data access instruction or the conditional branch instruction, it is not possible to interpret the next branch instruction or data access instruction.

In addition, according to the present embodiment, when the selected instruction is designated as the data access instruction by the pfreq, the control unit (3) can output the pfack, delete the result that is saved in the instruction type flags (230) to (237) within the prefetch address calculation unit (4), and carry out the processing of the prefetching request instruction only as targeting the instruction on and after the instruction in this entry.

According to the present structure, the prefetch address calculation unit (4) according to the present embodiment can effectively calculate the prefetching address by the prefetching request instruction in the same entry sufficiently as needed.

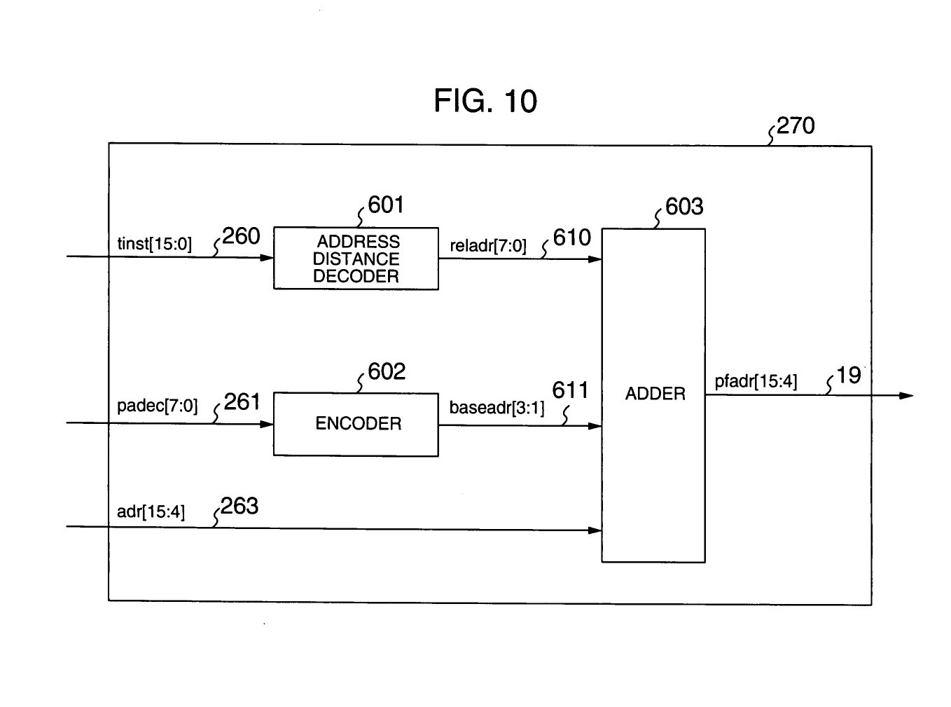

Next, the calculation for abstracting the entry including the target address of the prefetching request instruction that is selected by the target instruction selector (280) will be described below. FIG. 10 is the detailed view of an address calculation unit (270).

An address distance decoder (601) may derive the immediate value indicating a relative distance between the address of the instruction itself and the target address from the prefetching request instruction outputted to the tinst [15:0] and may output the immediate value to a relative address signal reladr [7:0] with a signal line 610. In the meantime, the immediate value of the prefetching request instruction of the CPU that is described according to the present embodiment is defined as 8 bits.

An encoder (602) encodes the padec [7:0] into 3 bits, and outputs a base address signal baseadr [3:1] to a signal line 611.

In this case, a relation between input and output of the encoder (602) is defined as follows:
8′b00000001−>3′b000
8′b00000010−>3′b001
8′b00000100−>3′b010
8′b00001000−>3′b011
8′b00010000−>3′b100
8′b00100000−>3′b101
8′b01000000−>3′b110
8′b10000000−>3′b111
other than the above−>3′b000

An adder (603) may calculate reladr [7:0] +baseadr [3:1]+{adr [15:4], 4′b0000}, and may output the calculation result of 15 to 4 bit to the pfadr [15:4].

In the meantime, receiving the pfadr [15:4] and the pfreq [1:0] to be outputted from the target instruction selector (280), the control unit (3) may perform the following control in accordance with its combination.

The prefetching request for the data access to pfreq [1:0]=2′b01: entry pfadr [15:4] is carried out.

The prefetching request for the conditional branching to pfreq [1:0]=2′b10: entry pfadr [15:4] is carried out.

The prefetching request for the non-conditional branching to pfreq [1:0]=2′b11: entry pfadr [15:4] is carried out.

Pfreq [1:0]=2′b00: no prefetching request

Next, the operation of the information processing apparatus according to the present embodiment will be described below.

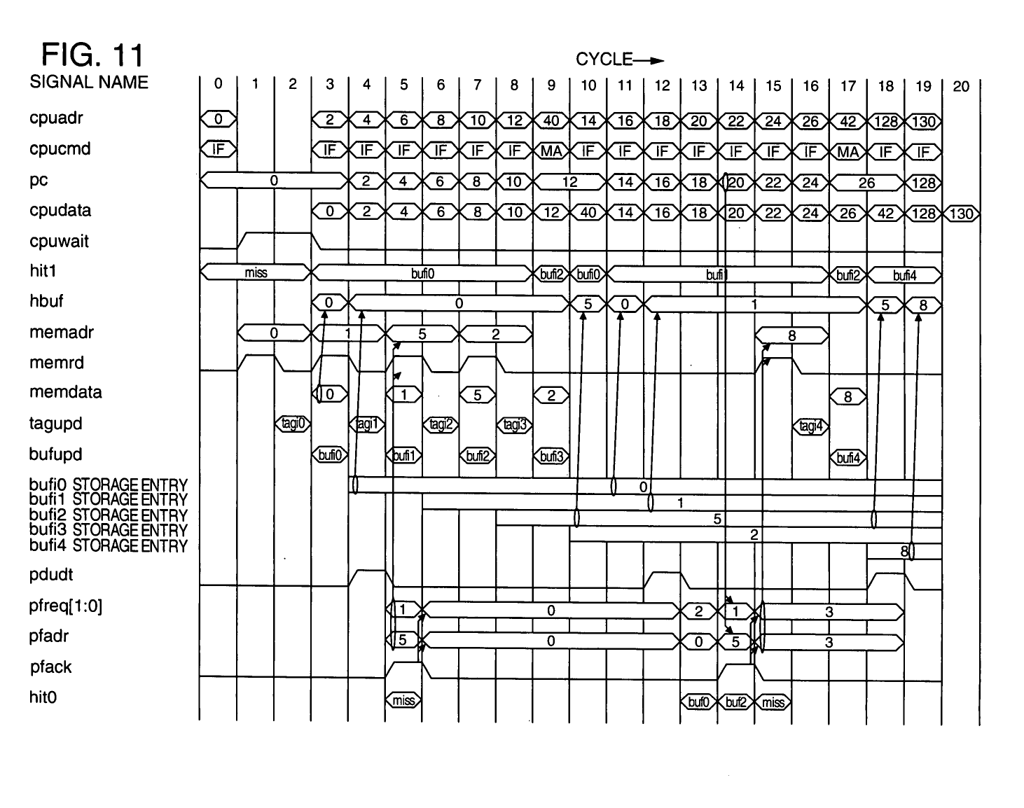

FIG. 11 is a timing chart showing the operation of the information processing apparatus according to the present embodiment of the present invention that has been described above. In this case, the present timing chart is an example of storing a program shown in FIG. 2 in a memory as shown in FIG. 5 and executing the program.

At first, at the cycle 0, the CPU (2) may fetch an instruction 0 of an address 0. At that point of time, there is notching stored in the prefetch buffer (7), so that a hit signal hit1 [4:0] from the read data selector (5) indicates buffer miss.

Next, in the cycle 1, receiving the buffer miss, the control unit (3) may output “0” to the memadr and may assert the memrd to start the access of the memory (1) to the entry 0. At the same time, asserting cpuwait, the control unit (3) may issue the request to stop the access to the memory (1) of the CPU (2) till the data is determined.

Next, in the cycle 2, the control unit (3) defines a storage place of the entry 0 as bufi0 of the prefetch buffer (7) and stores “0” indicating the entry o in tagi0 of the corresponding tag (6), so that the control (3) consequently outputs “0” to the memadr and outputs a signal to update the tagi0 to the tagupd.

Next, in the cycle 3, the memory (1) may output the series of instruction with a width of 128 bits including the instruction and the data of the entry 0 to the memdata. The read data selector (5) may select the memdata as the hbuf and may output the series of instruction of the entry 0. Further, the read data selector (5) may select the instruction 0 of the address 0 from the hbuf and may output it to the cpudata.

Since the cpudata is determined, the control unit (3) may transmit a restart permission of the access to the memory (1) to the CPU (2) by negating the cpuwait.

Further, in order to store the series of instruction of the entry 0 that is outputted to the memdata in the bufi0, the control unit (3) may output a signal to update the bufi0 into the bufupd.

As the control to the tagi0 and the bufi0 described in the cycle 1-3, the prefetch buffer (7) is updated with the access to the memory (1), and a series of operation is carried out in the order of the access to the memory (1), update of the tag (6), and the update of the prefetch memory (7). The operation of the prefetch buffer (7) to be described hereinafter is also carried out by the same procedure.

Further, the control unit (3) may output “1” to the memadr against that the entry 1 is accessed in future, may assert the memrd, and may start the access to the entry 1 for the memory (1).

The read data selector (5) may output the buffer 0 hit to the hit signal hit1 since the access to the entry 0 can be outputted from the bufi0 in the next cycle.

Further, the read data selector (5) may select the, instruction 0 of the address 0 from the memdata and may output it to the cpudata.

The CPU (2) may take in the instruction 0 of the address 0 from the cpudata and at the same time, may fetch the instruction 1 of the address 2.

Next, in the cycle 4, the read data selector (5) may select the buf0 as the hbuf and may output the series of instruction of the entry 0. Further, the read data selector (5) may select the instruction 1 of the address 2 from the hbuf and may output it to the cpudata.

The CPU (2) may take in the instruction 1 of the address 2 from the cpudata and at the same time, may fetch the instruction 1 of the address 2.

Hereinafter, the instruction fetch of a given instruction in the entry 0 continued to the cycle 10 is accessed through the bufi0 as same as fetch of the instruction 1 as described above. In other words, the necessary instruction is acquired not from the memory (1) but from the high-speed prefetch buffer (7). Thereby, without interruption of the access by the access latency of the memory (1), the processing is executed at a high speed. In addition, during this time, the access to the memory (1) by the instruction fetch does not occur, so that the control unit (3) can prefetch the series of instruction for the future access.

In this case, the control unit (3) may assert the pdupd so as to instruct the prefetch address calculation unit (4) to calculate the target address of the prefetching request instruction of the entry 0 in the buffer 0 before executing this instruction.

Next, in the cycle 5, the prefetch address calculation unit (4) may detect the instruction of “MOV @ (32, PC), R1” of the address 8 by the circuit described with reference to FIG. 8 and may output “1” indicating that the type of the instruction requesting the prefetch of the target address is the data access and “5” indicating the entry including the target address to the pfreq and the pfadr, respectively.

Since the entry 5 is not stored in the prefetch buffer (7) at that point of time, the hit signal hit0 [4:0] from the read data selector (5) indicates the buffer miss. Receiving the signal indicating the buffer miss, the control unit (3) may output the signals to update the tagi2 and the bufi2 in the tagupd and the bufupd so as to start the access to the entry 5 for the memory (1) and stores the series of instruction of the entry 5 in the bufi2.

In this case, the instruction of the address 8 that is selected as the instruction to request prefetching of the target address in the same cycle is the data access instruction. Therefore, the control unit (3) may assert the pfack so as to instruct the prefetch address calculation unit (4) to request prefetching of the target address of the prefetching request instruction on and after the address 8 of the entry 0.

Next, in the cycle 6, receiving assert of the pfack of the former cycle, the prefetch address calculation unit (4) clears the instruction type flag 4 storing the types of the instruction of the address 8. As a result, all of the stored values of the instruction type flags 0 to 7 become 0, and the prefetch address calculation unit (4) may output 0 to the pfadr and the pfreq, respectively.

As a result, the control unit (3) knows that there is no prefetching request instruction on and after the address 8 of the entry 0.

Next, in the cycle 9, the CPU (2) may output memory access (MA) in accordance with the instruction of the address 8, “MOV @ (32, PC), R1” to a cpumd. Since the entry 5 is prefetched in the bufi2 for this memory access, the CPU (2) can access the data 20 of the address 40 of the target address in the next cycle 10 without interruption of the access by latency of the memory access.

Next, in the cycle 11, the CPU (2) may fetch the instruction 8 of the address 16. Since the entry 1 is prefetched in the bufi1 for this instruction fetching, the CPU (2) can access the instruction 8 of the address 16 of the target address in the next cycle 12 without interruption of the access by latency of the memory access.

Hereinafter, the instruction fetching of the instruction located in the entry 1 continued to the cycle 16 can be executed at a high speed by accessing the bufi1 within the prefetch buffer (7) without interruption of the access by the access latency of the memory (1) as same as the above described fetching of the instruction 8. In addition, since the access to the memory (1) by the instruction fetching does not occur during this time, the control unit (3) can prefetch the series of instruction for the future access.

Next, in the cycle 12, the control unit (3) may assert the pdupd so as to instruct the prefetch address calculation unit (4) to calculate the target address of the prefetching request instruction of the entry 1 in the buffer 1 before executing this instruction.

Next, in the cycle 13, the prefetch address calculation unit (4) may detect the instruction of the address 18, “BT-18” by the circuit that is described with reference to FIG. 8 and may output “2” indicating that the instruction for requesting prefetch is the conditional branch instruction and the entry “0” of the target address to the pfreq and the pfadr, respectively. In this case, since the entry 0 is stored in the prefetch buffer bufi0, the hit signal hit0 [4:0] from the read data selector (5) indicates the buffer 0 hit to the prefetching request of the entry 0.

Receiving the signal indicating the buffer 0 hit, the control unit (3) does not carry out prefetching of the target address of the instruction “BT-1” of this address 18.

According to the present embodiment, the control unit (3) does not assert the pfack for instructing the prefetch address calculation unit (4) to request prefetching of the target address of the prefetching request instruction on and after the instruction of the address 18 receiving the prefetch request in accordance with the above-described algorithm.

Next, in the cycle 14, the CPU (2) may output “20” to the pc. Receiving this, the prefetch address calculation unit (4) may mask the output of the instruction type flag corresponding to the instruction “BT-18” of the address 18 by the circuit described with reference to FIG. 8 and FIG. 9. Then, detecting the instruction of the address 22, “MOV @ (20, PC), R1” as the next data access instruction, the prefetch address calculation unit (4) may output “1” indicating that the instruction for requesting prefetching is the data access instruction and the entry “5” of the target address to the pfreq and the pfadr, respectively.

In this case, since the entry 5 has been already stored in the prefetch buffer bufi2, as the hit signal hit0 [4:0] from the read data selector (5), one indicating the buffer hit is outputted.

Receiving a signal indicating the buffer 2 hit, the control unit (3) does not execute prefetching of the target address of this instruction, “MOV @ (20, PC), R1”.

Further, since the instruction of the address 22 requesting prefetching at the same cycle is the data access instruction, the control unit (3) may assert the pfack so as to instruct the prefetch address calculation unit (4) to request prefetching of the target address of the prefetch request instruction on and after the foregoing instruction of the address 22.

Next, in the cycle 15, the prefetch address calculation unit (4) may detect the instruction “BRA 102” of the address 26 by the circuit described with reference to FIG. 8 and may output “3” indicating that the instruction for requesting prefetching is the non-conditional branch instruction and the entry “8” of the target address to the pfreq and the pfadr, respectively.

At this point of time, since the entry 8 is not stored in the prefetch buffer, as the hit signal hit0 [4:0] from the read data selector (5), one indicating the buffer miss is outputted.

Receiving a signal indicating the buffer miss, the control unit (3) may start the access to the entry 8 for the memory (1) and may output a signal to update the tagi4 and the bufi4 so as to store the series of instruction of the entry 8 in the budi4 at the following cycles 16 and 17.

Next, in the cycle 17, the CPU (2) may output the memory access in accordance with the instruction of the address 22, “MOV @ (20, PC), R1”. Since the entry 5 is prefetched in the bufi12 in the cycle 5 for this memory access, without interruption of the access by the latency of the memory access, the CPU (2) can access the data of the target address (the data 21 of the address 42) in the next cycle 18.

Next, in the cycle 18, the CPU (2) may shift the flow of the program to the address 128 unconditionally in accordance with the instruction of the address 26, “BRA 102”, and may fetch the instruction 64 of the address 128.

Since the entry 8 is prefetched in the bufi4 at the cycle 15 for this instruction fetching, the CPU (2) can access the data of the target address (the instruction 64 of the address 128) at the next cycle 19 without interruption of the access by the latency of the memory access.

As described above, according to the information processing apparatus of the present embodiment, the program execution cycle becomes 20, and as compared to the execution cycle 36 when not using the present invention shown in FIG. 12, the performance is improved by 80% in the cycle number.

According to the present embodiment, detecting the branch instruction and the data access instruction from the series of instruction included in the entry that is stored in the prefetch buffer (7) at 1 cycle, it is possible to prefetch its target address. Therefore, the possibility that a buffer miss occurs because the prefetching is not in time for the access to the target address and the performance is deteriorated is reduced.

According to the present embodiment, depending on the types of the instruction for prefetching the target address, it is controlled whether or not the target address of the branch instruction and the data access instruction on and after the present instruction should be prefetched. In addition, by using a signal indicating the address of the instruction that is being executed presently, the prefetching of the target address of the branch instruction and the data access instruction that have been already executed is prevented and the target address is prefetched limiting to the branch instruction and the data access instruction to be executed later.

Therefore, limiting to the branch instruction and the data access instruction to be reliably executed, it is possible to prefetch the target address in the appropriate order. Hereby, the possibility that the necessary memory access is prevented due to the memory access for the useless prefetching and the performance is deteriorated is reduced.

In the meantime, various circuit structures that are described in the present embodiment is only an example for describing the present embodiment. If the above-described input and output are possible, the present invention is not limited to the circuit structure of the present embodiment.

As described above, according to the present embodiment, it is possible to effectively perform prefetching of the branch instruction and the data access instruction and to provide the high-performance information processing apparatus.

According to the above-described present invention, even in the program having many data accesses, it is possible to obtain an effect such that the effective prefetching can be performed and the high-performance information processing apparatus can be provided without depending on the types of the programs.

It should be further understood by those skilled in the art that although the foregoing description has been made on embodiments of the invention, the invention is not limited thereto and various changes and modifications may be made without departing from the spirit of the invention and the scope of the appended claims.

1. An information processing apparatus comprising:
a CPU;
a memory; and
a prefetch buffer for storing a series of instruction made of the predetermined number of instructions and data before said CPU executes the instruction or the data in said series of instruction;
wherein said information processing apparatus further includes prefetch address calculating means for selecting a prescribed branch instruction or data access instruction that is included in said series of instruction at a point of time when said series of instruction is stored in said prefetch buffer and calculating a target address of said selected instruction; and prefetch buffer storing means for determining whether or not said series of instruction including the instruction or the data of said target address that is calculated by said prefetch address calculating means is stored in said prefetch buffer, and when it is not stored therein, reading said series of instruction from said memory and storing it in said prefetch buffer.

2. The information processing apparatus according to claim 1,
wherein said prefetch address calculating means comprises instruction type determining means for determining the types of various instructions that are included in said series of instruction; and target instruction selecting means for selecting a prescribed branch instruction or data access instruction for calculating said target address from said series of instruction on the basis of a determination result of said instruction type determining means.

3. The information processing apparatus according to claim 2,
wherein said target instruction selecting means selects the branch instruction or the data access instruction to be executed at the most first from among said series of instruction on the basis of the determination result of said instruction type determining means.

4. The information processing apparatus according to claim 3,
wherein said target instruction selecting means comprises executed instruction determining means for specifying an instruction that is being executed by said CPU, and said target instruction selecting means selects the branch instruction or the data access instruction to be executed at the most first from among the instructions on and after the instruction that is specified by said executed instruction determining means in said series of instruction on the basis of the determination result of said instruction type determining means.

5. The information processing apparatus according to claim 4,
wherein said target instruction selecting means further selects the instruction to be executed at the most first from among the branch instructions or the data access instructions on and after said selected instruction in said series of instruction when said selected instruction is a branch conditional instruction in said data access instruction or said branch instruction.

6. The information processing apparatus according to claim 5,
wherein said prefetch address calculating means further comprises clearing means for clearing a determination result by said instruction type determining means corresponding to said selected instruction to be executed at the most first; and
said target instruction selecting means selects the instruction to be executed at the most first from among the instructions of which determination results are not cleared.

7. A prefetch buffer storing method for storing said series of instruction in said prefer buffer in an information processing apparatus comprising, a CPU, a memory and a prefetch buffer for storing a series of instruction made of the predetermined number of instructions and data before said CPU executes the instruction or the data in said series of instruction, comprising the steps of:
selecting a prescribed branch instruction or data access instruction that is included in said series of instruction when said series of instruction is stored in said prefetch buffer and calculates a target address of said selected instruction; and
determining whether or not said series of instruction including the instruction or the data of said target address that is calculated in said prefetch address calculating step is stored in said prefetch buffer; and when it is not stored, reading said series of instruction from said memory and storing it in said prefetch buffer.
